(19) United States
(12) Patent Application Publication
(10) Pub. No.: US 2025/0311155 A1
(43) Pub. Date: Oct. 2, 2025

(54) SENSOR SYSTEM FOR IMMERSION COOLING

(71) Applicant: Ascentek, Inc., Golden Valley, MN (US)

(72) Inventors: Todd Matvick, Becker, MN (US); Eivind Stenersen, St. Paul, MN (US); Justin Brinkman, New Hope, MN (US)

(21) Appl. No.: 19/083,133

(22) Filed: Mar. 18, 2025

Related U.S. Application Data
(60) Provisional application No. 63/571,804, filed on Mar. 29, 2024.

(51) Int. Cl. H05K 7/20

(52) U.S. Cl. CPC H05K 7/20272; H05K 7/20236

(57) ABSTRACT

Monitoring of cooling liquid in an electronics immersion cooling system. At least one sensor is provided in the cooling system, the sensor monitoring at least the dielectric properties of the cooling liquid. Operably connected to the sensor is an output that can relay the liquid properties to a user in a useful manner in order to determine if the liquid should be changed or augmented.

### CROSS REFERENCE

This application claims priority to U.S. provisional application 63/571,804 filed Mar. 29, 2024 and titled SENSOR FOR IMMERSION COOLING LIQUID, the entire disclosure of which is incorporated herein by reference.

### BACKGROUND

As cloud computer and data storage requirements increase, so does the size of data centers. The data storage devices (e.g., servers) produce heat and thus require cooling, which is commonly done with fans or other air moving equipment including on-board server fans, A/C compressors, and air-circulation fans. However, fans can be loud and require much energy. Recently, immersion cooling of the servers has emerged.

Immersion cooling reduces energy consumption by eliminating the air cooling infrastructure that includes fans, A/C compressors, necessary duct work, air handlers, and other active ancillary systems such as dehumidifiers. These air cooling systems and structures are replaced with liquid circulation pumps and heat exchangers and/or dry cooler systems.

In immersion cooling, the entire server is immersed in a dielectric, electrically non-conductive liquid, thus transferring the heat from the server to the liquid. Heat is removed from the liquid via heat exchangers. It is the electrical properties (or lack thereof), as well as physical and chemical characteristics of these liquids, that cause the liquids to remove heat from the electrical systems efficiently and safely.

### SUMMARY

This disclosure provides for monitoring of cooling liquid in immersion cooling systems, such as for electronic applications, by including at least one sensor operably connected to the cooling liquid, typically positioned in the cooling liquid. This disclosure provides a system that has the ability to ensure that thermal fluid (e.g., liquid) used in server cooling applications retains characteristics needed for proper function. Additionally, the disclosure provides a system that has the ability to ensure that thermal fluids (e.g., liquids) used in immersion cooled battery systems (E-Drive/BEV) retain proper physical and chemical characteristics for proper functionality.

In one particular example, this disclosure provides an immersion cooling system for electronics or batteries. The system has an enclosure for receiving electronics therein, the enclosure having an interior, a liquid outlet and a liquid inlet, a liquid recirculation line fluidly connected to the liquid outlet and to the liquid inlet, and an electrical-properties sensor operably connected to the interior of the enclosure, which may be within the enclosure or in the recirculation line between the outlet and the inlet.

This disclosure also provides various methods. In one example, a method for in situ monitoring the dielectric constant of a cooling liquid is provided. The cooling liquid may be for an immersion cooling system for electronics or batteries.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. These and various other features and advantages will be apparent from a reading of the following detailed description.

### BRIEF DESCRIPTION OF THE DRAWING

The described technology is best understood from the following Detailed Description describing various implementations read in connection with the accompanying drawing.

FIG. 1 is a diagram of an electronics system having a fluid sensor system.

FIG. 2 is a schematic diagram of an electronics system having a liquid sensor.

FIG. 3 is a schematic diagram of another electronics system having a liquid sensor.

FIG. 4 is a flow chart of a method of monitoring cooling liquid.

### DETAILED DESCRIPTION

As indicated above, this disclosure provides liquid sensing systems and methods for electronics immersion cooling, such as in data centers. The sensing systems and methods can be used with any immersion cooling system that utilizes a fluid (e.g., a liquid) to cool electronic devices, including immersion cooling systems of or from Nvidia, Supermicro, Microsoft, IBM, LiquidCool Solutions, Inc., Green Revolution Cooling (GRC), Asperitas, Submer, LiquidStack, Iceotope, Midas Immersion Cooling, for example. The fluid may be a nonconductive or dielectric liquid, for example, hydrocarbon or fluorocarbon based or glycol based, such as those designed for cold plate direct to chip cooling applications. The sensing systems can also be used in cold plate and immersion cooling systems for E-Drive applications such as those of Tesla, GM, Ford, Polaris, Bobcat, BRP or any other OEM application, as well as in battery packs similar to those of Xing Mobility, Packet Digital, and Kreisel.

In the following description, reference is made to the accompanying drawing that forms a part hereof and in which is shown by way of illustration at least one specific implementation. The following description provides additional specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples, including the figures, provided below. In some instances, a reference numeral may have an associated sub-label consisting of an upper-case letter to denote one of multiple similar components. When reference is made to a reference numeral without specification of a sub-label, the reference is intended to refer to all such multiple similar components.

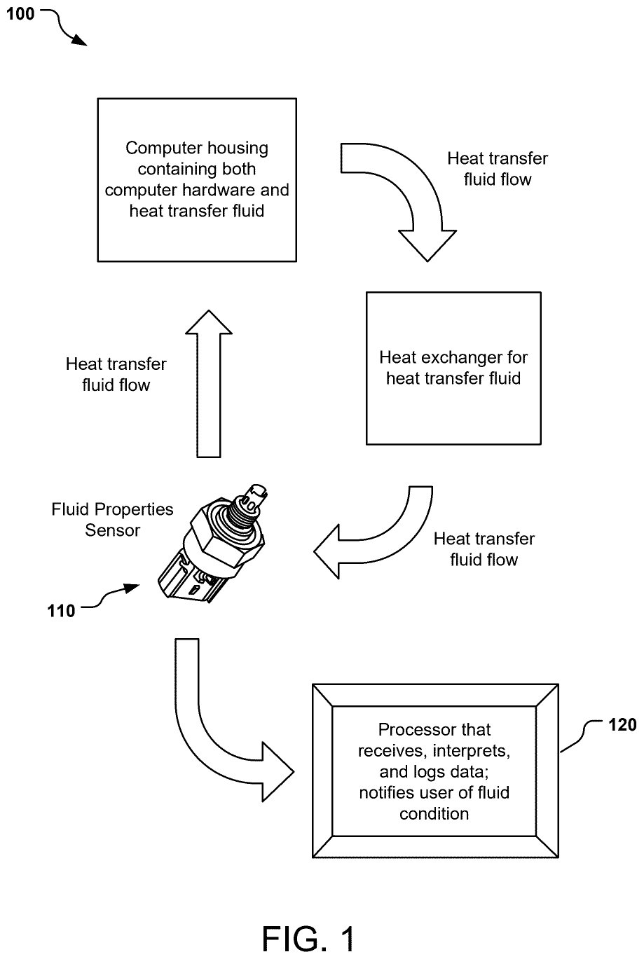

FIG. 1 shows a generic layout for an electronics immersion cooling system 100, the layout showing the liquid flow of the system. The system 100 includes a sensing system that includes a sensor 110 and a processor 120. The sensor 110 detects (senses) the fluid properties and operably transmits the property data to the processor 120. The processor 120 receives the property data, interprets the data (e.g., compares the data to predetermined thresholds), and logs or otherwise records the data. The processor 120 can initiate an alarm, advising a user if the fluid properties warrant an alarm; the processor 120 may additionally advise the user of the fluid properties even if an alarm is not warranted.

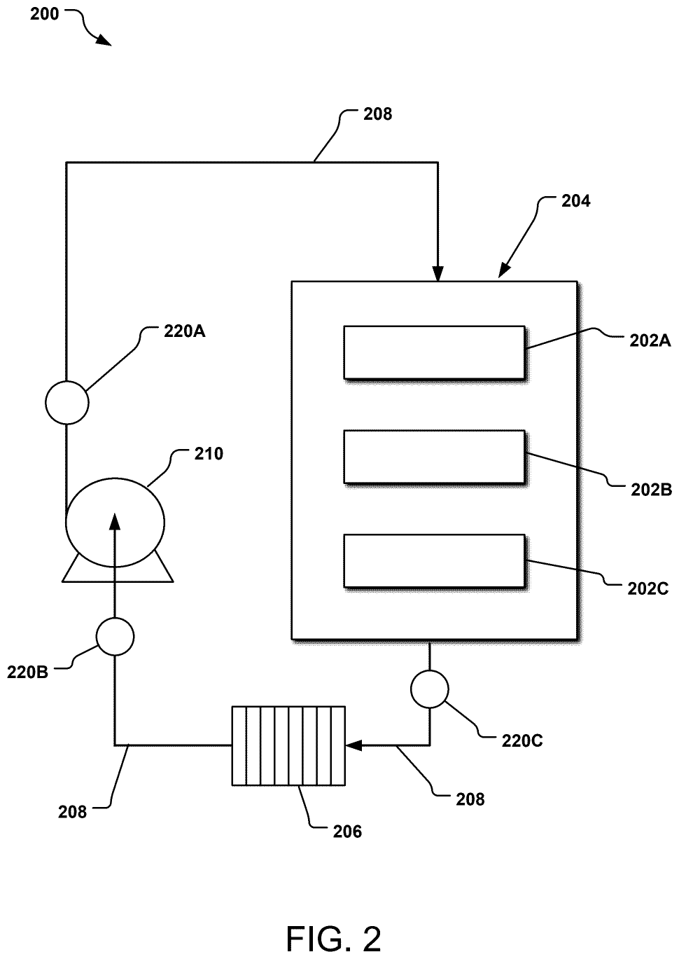

FIG. 2 shows a generic electronic system 200, such as a rack unit or other rack-mounted electronic equipment that may include one or more servers or other computer system(s). Particularly, the electronic system 200 has at least one electronic device 202; in this example, three devices 202A, 202B, 202C are shown. The electronic devices 202 are housed in a fluid-tight enclosure 204, which is filled with liquid, typically dielectric liquid. The devices 202 are on a rack, scaffold, support or otherwise supported so that the liquid freely flows around the devices 202. Although not shown, in some designs there may be baffles, channels, pumps, etc. to control the liquid flow in the enclosure 204.

The system 200 includes a cooling element 206, such as a heat exchanger, fluidly connected to the interior of the enclosure 204 via a circulation line 208. A pump 210 is present to move the liquid through the cooling element 206 and the line 208 and to return the liquid to the enclosure 204. Other arrangements of elements of the system may be used; for example, the cooling element 206 may be downstream of the pump 210.

The system 200 includes at least one sensor 220 that monitors the dielectric properties of the system's liquid; FIG. 2 shows three sensors 220A, 220B, 220C. It is noted that although three sensors 220 are shown, the system 200 may have only one sensor 220. Although the singular term “sensor” is used herein, it is noted that any number of individual sensors may be combined. In FIG. 2, each of the sensors 220 is located within the circulation line 208, although one or more sensors 2220 may be located in different locations of the system 200, such as within the enclosure 204 or within the cooling element 206. In the particular design shown, the sensor 220A is positioned downstream of the pump 210, the sensor 220B is positioned downstream of the cooling element 206 before the pump 210, and the sensor 220C is positioned downstream of the enclosure 204 before the cooling element 206. In many system configurations, the sensor 220 is positioned after the cooling element 206, the pump 210, and any other equipment (as is the sensor 220A), so that the sensor 220 is analyzing the liquid after any possible contamination sources. For example, the pump 210 may inadvertently introduce particular contaminants into the liquid, which a sensor positioned as is the sensor 220A could detect before the liquid returns to the enclosure 204.

The sensor 220 may monitor the dielectric properties of the cooling liquid by measuring the dielectric constant of the liquid, the electrical conductivity of the liquid, or the electrical resistivity of the liquid. As the cooling liquid ages and degrades, the dielectric constant increases. If the dielectric constant is too high, the opportunity for loss of signal integrity increases, as does the opportunity for arcing within and across the electronic device 202. As an example, a dielectric constant in the range of 0.5 to 2 is a desired value, in some systems as much as 2.5 is acceptable. The sensor 220 may generate an alarm, for example, if the determined dielectric constant is 3 or greater, in other implementations, 4 or greater.

Additionally, the sensor 220 may monitor the viscosity of the liquid, the pH of the liquid, temperature of the liquid, refractive index, or other properties. The sensor 220 may include a particulate counter, which may not only count the number of particles present but also register their size.

The sensor 220 may operate continuously or may be intermittent. The readings from the sensor 220 may be displayed on a screen or other readout, may be sent to a computer or other device. A warning or alarm system can be operably connected to the sensor 220 to alert an operator of elevated liquid properties.

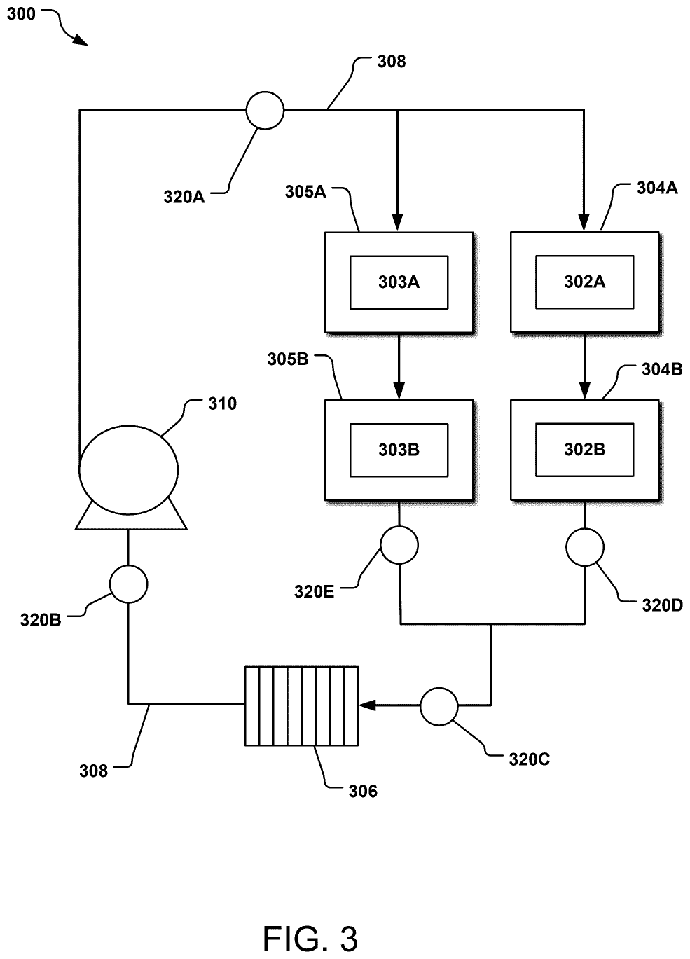

FIG. 3 shows another generic electronic system 300 having multiple electronic devices each in their own enclosure. The system 300 has a first electronic device 302A enclosed within an enclosure 304A filled with a dielectric liquid in series with a second electronic device 302B within an enclosure 304B, also filled with the dielectric liquid. The system 300 also has a third electronic device 303A within an enclosure 305A filled with a dielectric liquid in series with a fourth electronic device 303B within an enclosure 305B, also filled with the dielectric liquid. From the view of the dielectric liquid, the devices 302 are in parallel with the devices 303.

In fluid communication with and downstream of the electronic devices 302, 303 is a cooling element 306, such as a heat exchanger, connected via a circulation line 308. A pump 310 is present to move the liquid through the cooling element 306 and the line 308 and to return the liquid to the enclosures 304, 305. Other arrangements of elements of the system may be used; for example, the cooling element 306 may be downstream of the pump 310.

As in the system 200, the system 300 includes at least one sensor 320 that monitors the dielectric properties of the system's liquid; FIG. 2 shows five possible sensors 320A, 320B, 320C, 320D, 320E. Each of the sensors 320 is located within the circulation line 308. Specifically, the sensor 320A is positioned downstream of the pump 310 and the sensor 320B is positioned downstream of the cooling element 306 before the pump 310. The sensor 320C is positioned downstream of both of the enclosures 304, 305 before the cooling element 306, but the sensor 320D is positioned downstream of the enclosures 304 and the sensor 320E is downstream of the enclosures 305.

The sensor 320C is positioned in a location to measure the cooling liquid out of both sets of enclosures 304, 305, whereas the sensor 320D measures the liquid out of the enclosures 304 and the sensor 320E measures the liquid from the enclosures 305. In such a manner, a more precise determination of contamination origin can be determined (e.g., whether there is more liquid breakdown or contamination occurring in enclosures 304 or in enclosures 305).

Although multiple sensors 220, 320 have been shown in the systems 200, 300, in most systems only one or two sensors may be used, positioned in a location to best detect liquid deterioration and any presence of contaminants. As indicated above, a location before the liquid returns to the enclosure, yet downstream of most or all equipment that could degrade the liquid or introduce contaminants, is best.

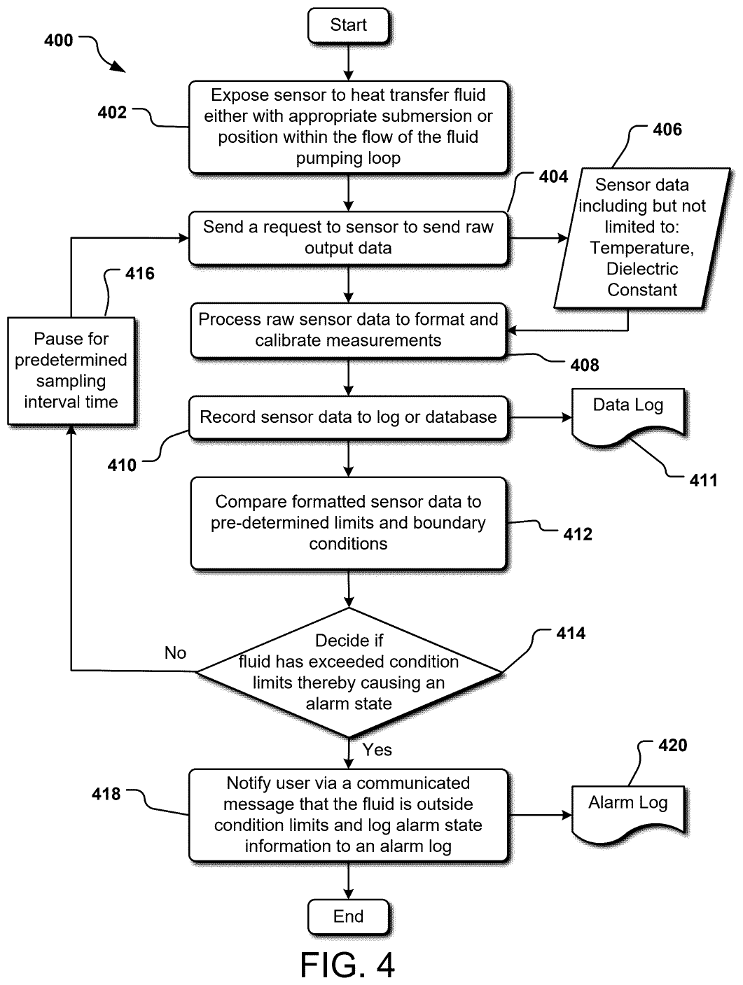

FIG. 4 provides an example method 400 for monitoring the quality of liquid in an immersion cooling system. The method 400 is a method of sensing fluid in use, storing data and providing a methodology to warn the users associated with the thermal fluid that a fluid failure is pending, thus advising that a change of dielectric fluid or other system maintenance is suggested.

In a first step 402, a sensor is exposed to a heat transfer fluid or liquid (e.g., a dielectric liquid) by appropriate positioning in a recirculation or pumping loop of the immersion cooling system. At a point in time, a user, or the system itself, requests data from the sensor in step 404. This raw data from the sensor may be, e.g., temperature, pH, or dielectric constant, of the liquid (step 406). The raw data is processed in step 408; the raw data may be calibrated and/or formatted. In step 410, the processed data is recorded, e.g., in a database or data log 411. The processed data is compared to preset limits/thresholds and conditions in step 412 and in step 414, it is decided whether or not the measured properties exceed acceptable limits, thus leading to an alarm state. If the data does not exceed the limits but is acceptable, a pause or delay occurs, in step 416, until the next sampling (step 402). If the data does exceed the limits, an alarm is raised and the user (e.g., equipment operator) is notified in step 418 and the alarm is recorded in 420.

The sensor systems and methods described herein can be used for any type of immersion cooling, including cold plate cooling and rack-based, with any cooling liquid. It is preferred to position the sensor in a recirculation line or other region where the liquid actively flows, rather than merely being stagnant or barely flowing, such as in an enclosure itself.

In addition to using the systems and methods in a data center, they may be used in, e.g., transportation vehicles (e.g., cars, trains) and other recreational vehicles. For example, electric vehicles utilize oil or an aqueous dielectric liquid to cool the batteries and/or other components; monitoring the liquid can be beneficial to the operation of the vehicle. A voltage leak, which can be due to breakdown of the dielectric fluid, can lead to a fire in the vehicle.

In summary, described herein are various implementations of sensor systems for monitoring the quality and electric properties of a liquid, such as a dielectric liquid for cooling electronics.

The above specification and examples provide a complete description of the structure and use of exemplary implementations of the invention. The above description provides specific implementations. It is to be understood that other implementations are contemplated and may be made without departing from the scope or spirit of the present disclosure. For example, elements or features of one example, design, embodiment or implementation may be applied to any other example, design, embodiment or implementation described herein to the extent such contents do not conflict. The above detailed description, therefore, is not to be taken in a limiting sense. While the present disclosure is not so limited, an appreciation of various aspects of the disclosure will be gained through a discussion of the examples provided.

As used herein, the singular forms “a”, “an”, and “the” encompass implementations having plural referents, unless the content clearly dictates otherwise. As used in this specification and the appended claims, the term “or” is generally employed in its sense including “and/or” unless the content clearly dictates otherwise.

Spatially related terms, including but not limited to, “bottom,” “lower”, “top”, “upper”, “beneath”, “below”, “above”, “on top”, “on,” etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

Since many implementations of the invention can be made without departing from the spirit and scope of the invention, the invention resides in the claims hereinafter appended. Furthermore, structural features of the different implementations may be combined in yet another implementation without departing from the disclosure or the recited claims.

What is claimed is:

1. An immersion cooling system comprising:
an enclosure for receiving electronics therein, the enclosure having an interior, a liquid outlet and a liquid inlet;
a liquid recirculation line fluidly connected to the liquid outlet and to the liquid inlet; and
an electrical-properties sensor operably connected to the interior of the enclosure.

2. The system of claim 1, wherein the electrical-properties sensor is positioned within the recirculation line between the outlet and the inlet.

3. The system of claim 1, wherein the electrical-properties sensor is configured to measure a dielectric constant of a liquid.

4. The system of claim 3, wherein the sensor is further configured to measure one or more of liquid viscosity, pH, refractive index, specific gravity and temperature.

5. The system of claim 1, further comprising a cooling element in liquid communication with the interior of the enclosure.

6. The system of claim 5, wherein the sensor is within the recirculation line downstream of the cooling element.

7. The system of claim 1, further comprising a liquid pump in liquid communication with the interior of the enclosure.

8. The system of claim 7, wherein the sensor is within the recirculation line downstream of the pump.

9. The system of claim 1 further comprising a processor configured to receive data from the sensor and compare the data to a preset threshold.

10. An immersion cooling system comprising:
an enclosure for receiving electronics therein, the enclosure having an interior, a liquid outlet and a liquid inlet;
a liquid recirculation line fluidly connected to the liquid outlet and to the liquid inlet;
a cooling element downstream of the liquid outlet and upstream of the liquid inlet and in liquid communication with the interior of the enclosure; and
an electrical-properties sensor within the recirculation line and operably connected to the interior of the enclosure.

11. The system of claim 10, further comprising a liquid pump downstream of the liquid outlet and upstream of the liquid inlet and in liquid communication with the interior of the enclosure.

12. The system of claim 11, wherein the sensor is downstream of the liquid pump.

13. The system of claim 10, wherein the sensor is downstream of the cooling element.

14. The system of claim 10, wherein the sensor is further configured to measure one or more of liquid viscosity, pH, refractive index, specific gravity and temperature.

15. The system of claim 9 further comprising a processor configured to receive data from the sensor and compare the data to a preset threshold.

16. The system of claim 15, the processor further configured to alert a user responsive to the data exceeding the preset threshold.
